(19) United States
(12) Patent Application Publication
(10) Pub. No.: US 2026/0351302 A1
(43) Pub. Date: Nov. 5, 2026

(54) MEMORY DEVICE, SYSTEM INCLUDING THE SAME

(71) Applicant: Samsung Electronics Co., Ltd., Suwon-si (KR)

(72) Inventor: Wangsoo KIM, Suwon-si (KR)

(73) Assignee: Samsung Electronics Co., Ltd., Suwon-si (KR)

(21) Appl. No.: 19/398,249

(22) Filed: Nov. 24, 2025

(30) Foreign Application Priority Data
Apr. 30, 2025 (KR) 10-2025-0057480

(51) Int. Cl. G11C 11/4093; G06F 13/42; H03K 3/356

(52) U.S. Cl. CPC G11C 11/4093; G06F 13/42; H03K 3/356017

(57) ABSTRACT

A memory device includes a data pad and a decision feedback equalizer configured to equalize a data signal received through the data pad. The decision feedback equalizer includes a first input circuit configured to generate a first feedback signal and a second feedback signal based on the data signal and a reference voltage according to a first clock signal, and a first latch circuit configured to generate a first output signal and a second output signal based on the first feedback signal and the second feedback signal. The memory device further includes a first impedance circuit included in the first input circuit and configured to adjust frequency responses of the first feedback signal and the second feedback signal, and/or a second impedance circuit included in the first latch circuit and configured to adjust frequency responses of the first output signal and the second output signal.

### CROSS-REFERENCE TO RELATED APPLICATION

This U.S. non-provisional application claims priority under 35 U.S.C. § 119 to Korean Patent Application No. 10-2025-0057480, filed in the Korean Intellectual Property Office on Apr. 30, 2025, the entire contents of which are hereby incorporated by reference.

### BACKGROUND

Some example embodiments relate to a memory device and a system including the memory device.

Electronic devices may transmit and receive electrical signals with other electronic devices through a channel. During transmission and reception of the signals, distortion may occur due to a response characteristic of the channel, noise, and the like. Because such distortion may cause errors, for example, erroneous data recovery at a receiving device, different types of equalizers are used to compensate for the distortion of the signals.

As transmission speed has increased with technological advancement, signal distortion has increased. For example, distortion may increase in high-frequency bands, and therefore it is advantageous for technology to compensate for the distortion. As semiconductor integration has increased, it is desirable to reduce an overall circuit area and sizes of the components, and effectively perform signal compensation.

### SUMMARY

Some example embodiments provide a memory device and a system including the memory device.

Example embodiments of the present disclosure are not limited to those mentioned herein, and other example embodiments not mentioned will be clearly understood by those of ordinary skill in the art from the following description.

In some example embodiments, a memory device includes a data pad configured to receive a data signal, and a decision feedback equalizer configured to equalize the data signal received through the data pad. The decision feedback equalizer includes a first input circuit configured to generate a first feedback signal and a second feedback signal based on the data signal and a reference voltage according to a first clock signal, and a first latch circuit configured to generate a first output signal and a second output signal based on the first feedback signal and the second feedback signal. The memory device further includes at least one of a first impedance circuit included in the first input circuit and configured to adjust frequency responses of the first feedback signal and the second feedback signal, or a second impedance circuit included in the first latch circuit and configured to adjust frequency responses of the first output signal and the second output signal.

In some example embodiments, a memory device includes a data pad configured to receive a data signal, and a decision feedback equalizer including a plurality of equalization blocks configured to equalize the data signal received through the data pad. Each of the plurality of equalization blocks includes an input circuit configured to generate a first feedback signal and a second feedback signal based on the data signal and a reference voltage according to a clock signal, and a latch circuit configured to generate a first output signal and a second output signal based on the first feedback signal and the second feedback signal. The input circuit includes at least one of a source-degeneration circuit or a middle-frequency equalizer configured to adjust frequency responses of the first feedback signal and the second feedback signal. The latch circuit includes an active inductor circuit configured to adjust frequency responses of the first output signal and the second output signal.

In some example embodiments, a memory system includes a host device, and a memory device configured to receive a data signal from the host device through a memory interface including a decision feedback equalizer. The decision feedback equalizer includes an input circuit configured to generate a first feedback signal and a second feedback signal based on the data signal and a reference voltage according to a clock signal, and a latch circuit configured to generate a first output signal and a second output signal based on the first feedback signal and the second feedback signal. The input circuit includes a first impedance circuit configured to provide voltage gain to a difference between the data signal and the reference voltage. The latch circuit includes a second impedance circuit configured to provide voltage gain to a difference between the first feedback signal and the second feedback signal generated based on the first impedance circuit.

According to some example embodiments of the present disclosure, by including impedance circuits in an input circuit that is configured to receive the data signal and in a latch circuit that is configured to receive feedback signals, voltage gain according to frequency may be adjusted within the decision feedback equalizer itself. For example, high-frequency gain may be increased. By increasing voltage gain in a dual structure through the respective impedance circuits of the input circuit and the latch circuit, accuracy of data reception in a high-speed interface environment may be improved, and bit-error rate (BER) may be reduced. In addition, a timing margin may be improved.

According to some example embodiments of the present disclosure, because the decision feedback equalizer may amplify the signal through placement of the impedance circuits, the data signal may be directly received without a separate circuit, such as a continuous-time linear equalizer (CTLE), that pre-compensates/amplifies the received data signal. Therefore, a circuit area of the equalizer may be reduced and power consumption for performing an equalization operation may also be reduced.

According to some example embodiments of the present disclosure, by disposing the impedance circuit in the input circuit that receives the data signal to amplify voltage gain, attenuation or distortion of a high-frequency component of the signal may be compensated or reduced. Furthermore, because the impedance circuit may be configured to perform a middle-frequency equalization function that also amplifies voltage gain for a middle-frequency component, both a high-frequency band and a middle-frequency band may be improved, and an influence of inter-symbol interference may be more effectively suppressed.

According to some example embodiments of the present disclosure, by adjusting impedance values of elements included in the input circuit based on characteristics of the channel and/or an operating environment (for example, transmission speed), frequency response(s) of the feedback signals may be variably controlled, and thus the decision feedback equalizer may dynamically cope with or adjust to various environments. Through this, the equalizer may be controlled to be optimized for both a high-speed operating environment and a low-speed operating environment.

According to some example embodiments of the present disclosure, in order to more effectively perform equalization in a high-speed operating environment, the received data signal may be processed in parallel. For example, by dividing and processing data received at high speed, margins in power and process may be improved, an offset tolerance range may be improved, and a BER margin may increase.

According to some example embodiments of the present disclosure, by including the impedance circuit in the latch circuit that is configured to receive the feedback signals to amplify voltage gain, attenuation or distortion of a high-frequency component of the signals may be compensated or corrected. In addition, by implementing respective sub-impedance circuits so that a signal whose frequency response was adjusted is re-amplified in the latch circuit, improvement for the high-frequency band may be performed more effectively.

According to some example embodiments of the present disclosure, by adjusting impedance values of variable elements included in the latch circuit based on characteristics of the channel and/or an operating environment (for example, transmission speed), frequency response(s) of output signals may be variably controlled, and thus the decision feedback equalizer may dynamically cope with or adjust to various environments. As a result, the equalizer may be optimized for both a high-speed operating environment and a low-speed operating environment.

Technical effects obtainable through the present disclosure are not limited to those described above. Technical effects not mentioned will be clearly understood by those of ordinary skill in the art from the following description of example embodiments.

### BRIEF DESCRIPTION OF THE DRAWINGS

FIG. 1 is a block diagram illustrating transmission and reception operations of a data signal according to some example embodiments of the present disclosure.

FIG. 2 is a block diagram illustrating a data-signal reception process according to some example embodiments of the present disclosure.

FIG. 3 is a block diagram illustrating a structure of a decision feedback equalizer according to some example embodiments of the present disclosure.

FIG. 4 is a circuit diagram illustrating a structure of an input circuit according to some example embodiments of the present disclosure.

FIG. 5 illustrates some example embodiments of a control circuit that controls the input circuit of FIG. 4.

FIG. 6 is a block diagram illustrating a structure of a decision feedback equalizer according to some example embodiments of the present disclosure.

FIG. 7 is a circuit diagram illustrating a structure of a latch circuit according to some example embodiments of the present disclosure.

FIG. 8 illustrates some example embodiments of a control circuit that controls the latch circuit of FIG. 7.

FIG. 9 is a circuit diagram illustrating a structure of a latch block according to some example embodiments of the present disclosure.

FIG. 10 and FIG. 11 are circuit diagrams illustrating an input circuit and a latch circuit, respectively, according to some example embodiments of the present disclosure.

FIG. 12 is a timing diagram illustrating signals of the decision feedback equalizer of FIGS. 10 and 11.

FIG. 13 is a diagram explaining effects of the decision feedback equalizer of FIGS. 10 and 11.

FIG. 14 is a block diagram illustrating a memory system according to some example embodiments of the present disclosure.

### DETAILED DESCRIPTION

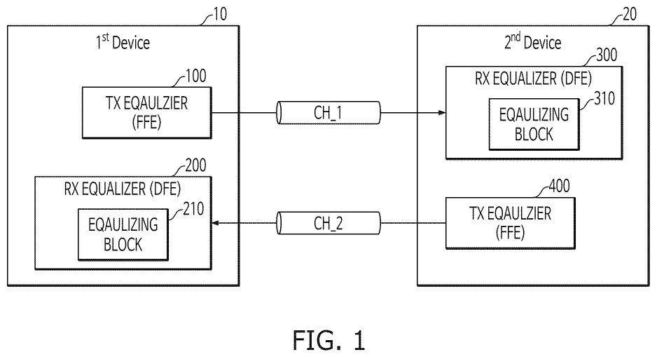

Hereinafter, some example embodiments of the present disclosure will be described with reference to FIGS. 1 through 14. The same reference numerals throughout the specification may refer to the same elements.

In the present disclosure, “each of a plurality of A” may refer to each of all components included in the plurality of A or may refer to each of some components included in the plurality of A.

FIG. 1 is a block diagram illustrating transmission and reception operations of a data signal according to some example embodiments of the present disclosure. A first device 10 and a second device 20 may be referred to as electronic devices. In an example, each of the first device 10 and the second device 20 may be a computing device such as a portable communication terminal, a personal digital assistant (PDA), a portable media player (PMP), a smartphone, a wearable device, a personal computer, a server, or a notebook computer. In other examples, each of the first device 10 and the second device 20 may be various hardware components included in a single user device, for example, a processor, a memory device, a storage device, or a control device. In some example embodiments, the first device 10 may be a host device, and the second device 20 may be a memory device. However, example embodiments are not limited thereto; in some example embodiments a transmitting-and-receiving system may be implemented as a single electronic device. For example, the first device 10 and the second device 20 may be components or intellectual-property (IP) blocks included in a single electronic device and may be implemented at a circuit, module, chip, and/or package level. In some example embodiments, the first device 10 and the second device 20 may also be implemented as a single circuit, module, chip, and/or package-level entity.

The first device 10 and the second device 20 may exchange data signals with each other through a first channel CH_1 and a second channel CH_2. The first channel CH_1 and the second channel CH_2 may be signal lines (for example, wired communication channels) electrically connecting the first device 10 and the second device 20, or may be wireless communication channels. Communication circuits of the first device 10 and the second device 20 may transmit and receive various types of signals, such as electrical signals, optical signals, or wireless signals.

While the first device 10 and the second device 20 transmit and receive data signals, distortion may occur due to noise caused by transmission characteristics of the first channel CH_1 and/or the second channel CH_2 or due to external factors. In this case, information transmitted from the first device 10 and information received at the second device 20 may differ, which may cause an error or malfunction in the second device 20. To reduce error or malfunction, the first device 10 and/or the second device 20 may include components that compensate for signal distortion caused by transmission characteristics and noise of the channels.

In some example embodiments, distortion may occur when the first device 10 transmits a data signal to the second device 20. Accordingly, the first device 10 may include a transmitting equalizer (TX equalizer) 100 configured to compensate for signal distortion due to transmission characteristics and noise of the first channel CH_1. The second device 20 may include a receiving equalizer (RX equalizer) 300 configured to compensate for signal distortion due to transmission characteristics and noise of the first channel CH_1. The second device 20 may further include a sequence estimator configured to estimate data (or symbols or sequences) based on the received data signal. Likewise, distortion may occur when the second device 20 transmits a data signal to the first device 10. Accordingly, the second device 20 may include a transmitting equalizer 400 configured to compensate for signal distortion due to transmission characteristics of the second channel CH_2, and the first device 10 may include a receiving equalizer 200 configured to compensate for signal distortion due to transmission characteristics of the second channel CH_2.

In some example embodiments, the transmitting equalizers 100 and 400 may be implemented as feed-forward equalizers (FFEs). The transmitting equalizers 100 and 400 may respectively receive data to be transmitted to the other device, perform compensation operations to reduce distortion, and output data signals. In some example embodiments, the receiving equalizers 200 and 300 may be implemented as decision feedback equalizers (DFEs). However, example embodiments are not limited thereto. For example, the transmitting equalizer 100 and the receiving equalizer 300 may be implemented as at least one of various types of signal-compensation circuits. The receiving equalizers 200 and 300 may respectively receive data signals from the other device, perform compensation operations to reduce distortion of the data signals, and output data. Each of the receiving equalizers 200 and 300 may include an equalization block 210, 310 configured to perform an equalization operation. In some example embodiments, each of the equalization blocks 210 and 310 may include impedance circuit(s) configured to adjust voltage gain in a specific or given or desired frequency band (for example, a middle-frequency and/or high-frequency band) to perform an enhanced equalization operation in a high-speed operating environment.

In some example embodiments, the transmitting equalizer 100 and the receiving equalizer 200 of the first device 10 are illustrated separately, and the transmitting equalizer 400 and the receiving equalizer 300 of the second device 20 are illustrated separately. However, example embodiments are not limited thereto. For example, the transmitting equalizer 100 and the receiving equalizer 200 may be implemented as a single circuit (for example, a communication circuit or an interface circuit), and the transmitting equalizer 400 and the receiving equalizer 300 may be implemented as a single circuit (for example, a communication circuit or an interface circuit).

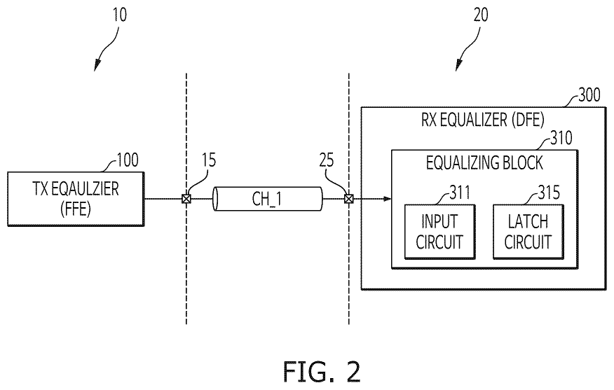

FIG. 2 is a block diagram illustrating a data-signal reception process according to some example embodiments of the present disclosure. As described above with reference to FIG. 1, the first device 10 may transmit a data signal to the second device 20 through the first channel CH_1. Hereinafter, the first channel CH_1 and the receiving equalizer 300 of the second device 20 are discussion below for sake of explanation. The same or similar discussion may apply to the second channel CH_2 and the first device 10. Referring to FIG. 2, the transmitting equalizer 100 of the first device 10, which has received data to be transmitted, may output a data signal through a first data pad 15. The receiving equalizer 300 of the second device 20 may receive the data signal through a second data pad 25. In some example embodiments, a first equalization block 310 (for example, a first input circuit 311 of the first equalization block 310) of the receiving equalizer 300 may directly receive the data signal through the second data pad 25. In other words, the receiving equalizer 300 may directly receive the data signal without a separate circuit (for example, a CTLE) that pre-compensates the received data signal.

In some example embodiments, due to various factors such as transmission characteristics (for example, skin effect, dielectric loss) and noise of the first channel CH_1 in communication between the first device 10 and the second device 20, the first channel CH_1 may exhibit a low-pass frequency response characteristic. Accordingly, bandwidths of the first channel CH_1 may be limited or reduced in high-speed operation, and as a result bandwidths of the data signals may decrease. This may weaken high-frequency (or middle-frequency) components of the data signals transmitted through the first channel CH_1 and may cause inter-symbol interference (ISI) in a time domain.

The receiving equalizer 300 may remove inter-symbol interference occurring in the data signals transmitted through the first channel CH_1 and may output data. The receiving equalizer 300 may output data by reflecting predetermined or desired or given coefficient(s) on previous symbols, current symbols, and subsequent symbols to remove inter-symbol interference. As described above, the receiving equalizer 300 may be implemented in a decision feedback equalizer structure. The receiving equalizer 300 may perform a decision feedback equalization operation on the received data signals according to some example embodiments of the present disclosure based on the first input circuit 311 and the first latch circuit 315 of the first equalization block 310.

The receiving equalizer 300 may be a one-tap equalizer. For example, the receiving equalizer 300 may cancel inter-symbol interference for a symbol that is one period earlier. However, example embodiments are not limited thereto. For example, the receiving equalizer 300 may be extended to an n-tap structure (where n is a natural number of two or more).

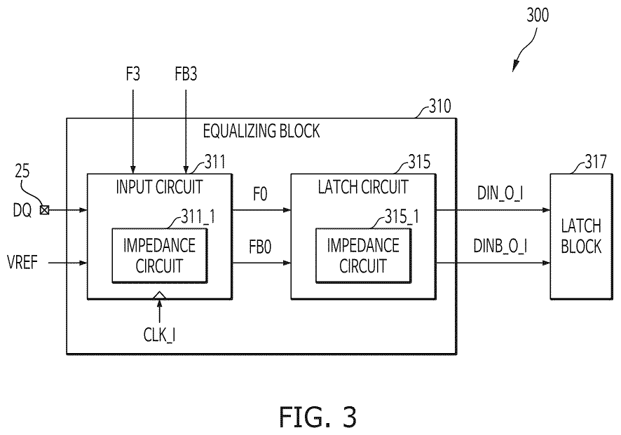

FIG. 3 is a block diagram illustrating a structure of a decision feedback equalizer according to some example embodiments of the present disclosure. Referring to FIG. 3, a receiving equalizer 300 having a decision feedback equalizer structure may perform an equalization operation based on a first equalization block 310 and a latch block 317. The first equalization block 310 may include a first input circuit 311 and a first latch circuit 315.

First, the second data pad 25 may receive a data signal DQ. For example, the data signal DQ may be a signal transmitted from a host through a channel. In some example embodiments, the data signal DQ received through the second data pad 25 may be directly provided to the first input circuit 311.

The first input circuit 311 may compare the data signal DQ with a reference voltage VREF based on a first clock signal CLK_I and may generate a first feedback signal F0 and a second feedback signal FB0. In some example embodiments, the first input circuit 311 may adjust frequency responses of the first feedback signal F0 and the second feedback signal FB0 based on a first impedance circuit 311_1.

In some example embodiments, the first impedance circuit 311_1 may adjust voltage gain for a difference between the data signal DQ and the reference voltage VREF according to frequency based on internal impedance. For example, the first impedance circuit 311_1 may provide high-frequency gain to the difference between the data signal DQ and the reference voltage VREF. For example, in a high-speed operating environment, the difference between the data signal DQ and the reference voltage VREF may include a relatively larger high-frequency component, and due to various factors such as transmission characteristics of the channel and noise, the channel may exhibit a low-pass frequency response characteristic. Accordingly, a high-frequency component of the data signal transmitted through the channel may be weakened. In this case, by adjusting voltage gain according to frequency for the difference between the data signal DQ and the reference voltage VREF, the first impedance circuit 311_1 may provide high-frequency gain. For example, the first impedance circuit 311_1 may operate as a high-pass filter (HPF). Accordingly, by the high-frequency gain provided by the first impedance circuit 311_1, frequency responses of the first feedback signal F0 and the second feedback signal FB0 may be adjusted, and a difference between the first feedback signal F0 and the second feedback signal FB0 may increase, for example, in the high-frequency band.

The first latch circuit 315 may generate a first output signal DIN_O_I and a second output signal DINB_O_I based on the first feedback signal F0 and the second feedback signal FB0. For example, the first latch circuit 315 may generate the first output signal DIN_O_I and the second output signal DINB_O_I by latching a difference between the first feedback signal F0 and the second feedback signal FB0. In some example embodiments, the first latch circuit 315 may adjust frequency responses of the first output signal DIN_O_I and the second output signal DINB_O_I based on a second impedance circuit 315_1. The second impedance circuit 315_1 may include sub-impedance circuits corresponding to the first feedback signal F0 and the second feedback signal FB0, respectively, and each sub-impedance circuit may adjust frequency responses of the first output signal DIN_O_I and the second output signal DINB_O_I, respectively.

In some example embodiments, the second impedance circuit 315_1 may adjust voltage gain for a difference between the first feedback signal F0 and the second feedback signal FB0 according to frequency. For example, based on the sub-impedance circuits, the second impedance circuit 315_1 may provide high-frequency gain to each of the first feedback signal F0 and the second feedback signal FB0. In a high-speed operating environment, the first feedback signal F0 and the second feedback signal FB0 may include a relatively large high-frequency component. In this case, by adjusting voltage gain according to frequency for each of the first feedback signal F0 and the second feedback signal FB0, the second impedance circuit 315_1 may provide high-frequency gain. Accordingly, by the high-frequency gain provided by the second impedance circuit 315_1, frequency responses of the first output signal DIN_O_I and the second output signal DINB_O_I may be adjusted, and a difference between the first output signal DIN_O_I and the second output signal DINB_O_I may increase, for example, in the high-frequency band.

The latch block 317 may restore a data value included in the data signal DQ based on the first output signal DIN_O_I and the second output signal DINB_O_I. To restore the data included in the data signal DQ without or with reduced error, the difference between the first feedback signal F0 and the second feedback signal FB0 is latched, and the first latch circuit 315 may with relatively higher precision latch the difference as the difference becomes larger. The first impedance circuit 311_1 of the first input circuit 311 may increase voltage gain for the difference between the data signal DQ and the reference voltage VREF and may provide the increased voltage gain to the first latch circuit 315. The second impedance circuit 315_1 of the first latch circuit 315 may increase voltage gain before latching the first feedback signal F0 and the second feedback signal FB0, thereby increasing the difference between a logic-low level and a logic-high level of the first output signal DIN_O_I and the second output signal DINB_O_I.

The receiving equalizer 300 according to some example embodiments is not limited thereto and may further include a plurality of latch circuits. In some example embodiments, the receiving equalizer 300 may be implemented with a k-stage (k is an integer of two or more) input structure and/or a k-stage latch structure. For example, the receiving equalizer 300 may further include an input latch circuit configured to latch the data signal to determine a data value included in the data signal, an intermediate latch circuit configured to receive a signal latched from the input latch circuit, and an output latch circuit configured to output, in synchronization with a predetermined clock signal, an output received from the intermediate latch circuit. The receiving equalizer 300 may be a decision feedback equalizer implemented in various input and/or latch stage structures.

The first input circuit 311 of the first equalization block 310 may receive feedback signals F3 and FB3 generated by another equalization block. To reduce or compensate inter-symbol interference or distortion, the first input circuit 311 may drive and/or output the data signal DQ and the reference voltage VREF based on the received feedback signals F3 and FB3. Likewise, feedback signals F0 and FB0 generated by the first input circuit 311 of the first equalization block 310 may be provided to an input circuit of another equalization block, and the equalization block may drive and/or output an input signal based on the feedback signals F0 and FB0. A decision feedback structure for equalizing a current input signal using past bit values may be implemented. At this time, because each equalization block receives feedback signals from one other equalization block, the receiving equalizer 300 having a decision feedback equalizer structure may be referred to as a one-tap decision feedback equalizer.

A decision feedback equalizer according to some example embodiments of the present disclosure may adjust voltage gain according to frequency by disposing impedance circuits in an input circuit that receives a data signal and in a latch circuit that receives feedback signals. For example, high-frequency gain may be increased. By increasing voltage gain in a dual structure through the respective impedance circuits of the input circuit and the latch circuit, accuracy of data reception in a high-speed interface environment may be improved, and bit-error rate (BER) may be reduced. In addition, a timing margin may be improved or increased.

In addition, because a decision feedback equalizer according to some example embodiments of the present disclosure may amplify a signal through placement of impedance circuits, the data signal may be directly received without a separate circuit (for example, a CTLE) that pre-compensates/amplifies the received data signal. Therefore, a circuit area of the equalizer may be reduced, and power consumption for performing an equalization operation may also be reduced.

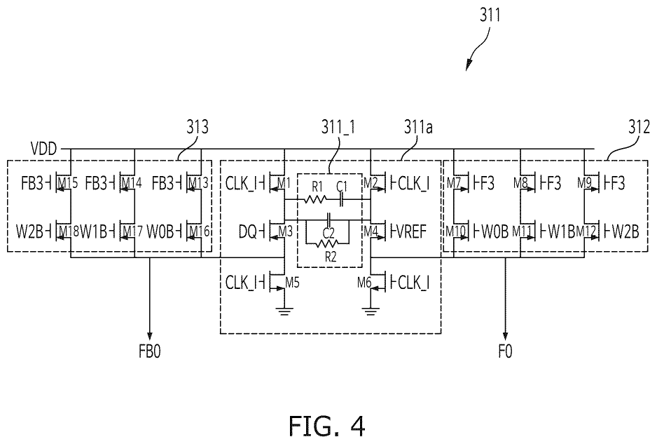

FIG. 4 is a circuit diagram illustrating a structure of an input circuit according to some example embodiments of the present disclosure. The first input circuit 311 may include a tap circuit including a first receiving circuit 311a, a first drive circuit 312, and a second drive circuit 313. The first receiving circuit 311a may receive the reference voltage VREF, the data signal DQ, and the first clock signal CLK_I.

In some example embodiments, to receive and compare the reference voltage VREF and the data signal DQ, the first receiving circuit 311a may include a first switch transistor M1, a second switch transistor M2, a first input transistor M3, a second input transistor M4, a first NMOS (n-channel metal-oxide-semiconductor) transistor M5, a second NMOS transistor M6, and the first impedance circuit 311_1. The first switch transistor M1, the second switch transistor M2, the first input transistor M3, and the second input transistor M4 may be PMOS (p-channel metal-oxide-semiconductor) transistors. A drain terminal of the first switch transistor M1 may be connected to a power-supply voltage VDD, a source terminal thereof may be connected to one end of the first impedance circuit 311_1, and the first clock signal CLK_I may be applied to a gate terminal thereof. A drain terminal of the second switch transistor M2 may be connected to the power-supply voltage VDD, a source terminal of the second switch transistor M2 may be connected to the other end of the first impedance circuit 311_1, and the first clock signal CLK_I may be applied to a gate terminal of the second switch transistor M2. A drain terminal of the first input transistor M3 may be connected to one end of the first impedance circuit 311_1, a source terminal of the first input transistor M3 may output the second feedback signal FB0, and the data signal DQ may be applied to a gate terminal of the first input transistor M3. A drain terminal of the second input transistor M4 may be connected to the other end of the first impedance circuit 311_1, a source terminal of the second input transistor M4 may output the first feedback signal F0, and the reference voltage VREF may be applied to a gate terminal of the second input transistor M4. The first input transistor M3 may directly receive the data signal DQ through the data pad, and the second input transistor M4 may receive the reference voltage VREF for comparison with the data signal DQ. In addition, the first switch transistor M1 and the second switch transistor M2 may be switched according to the first clock signal CLK_I so that the input transistors M3 and M4 are connected to the power-supply voltage VDD.

A drain terminal of the first NMOS transistor M5 may be connected to a source terminal of the first input transistor M3, a source terminal of the first NMOS transistor M5 may be connected to a ground potential, and the first clock signal CLK_I may be applied to a gate terminal of the first NMOS transistor M5. A drain terminal of the second NMOS transistor M6 may be connected to a source terminal of the second input transistor M4, a source terminal of the second NMOS transistor M6 may be connected to the ground potential, and the first clock signal CLK_I may be applied to a gate terminal of the second NMOS transistor M6. The first NMOS transistor M5 and the second NMOS transistor M6 may be switched according to the first clock signal CLK_I so that the respective input transistors M3 and M4 are connected to the ground potential.

The first input circuit 311 may compare the reference voltage VREF and the data signal DQ based on the first clock signal CLK_I and may generate the first feedback signal F0 and the second feedback signal FB0. In some example embodiments, the first input circuit 311 may adjust frequency responses of the first feedback signal F0 and the second feedback signal FB0 based on the first impedance circuit 311_1. In some example embodiments, the first impedance circuit 311_1 may provide voltage gain according to frequency for a difference between the reference voltage VREF and the data signal DQ. For example, high-frequency gain may be provided for the difference between the reference voltage VREF and the data signal DQ. Therefore, even when a high-frequency component is weakened or lowered due to transmission characteristics of the channel in a high-speed operating environment, by adjusting voltage gain through the first impedance circuit 311_1, a difference between the first feedback signal F0 and the second feedback signal FB0 may increase or improve.

In some example embodiments, the first impedance circuit 311_1 may include a first capacitor C1 and a first resistor R1 connected in series. The first impedance circuit 311_1 may adjust voltage gain of a middle-frequency band based on the first capacitor C1 and the first resistor R1. The first impedance circuit 311_1 may reduce the weakening or reduction of the middle-frequency component. The first impedance circuit 311_1 is not limited thereto and may be implemented in different structures configured to amplify voltage gain in the middle-frequency band.

In some example embodiments, the first impedance circuit 311_1 may include a second capacitor C2. The first impedance circuit 311_1 may adjust voltage gain of a high-frequency component of the input signal based on the second capacitor C2. The first impedance circuit 311_1 may operate as a high-pass filter (HPF). For example, the first impedance circuit 311_1 may be referred to as a source-degeneration circuit. The first impedance circuit 311_1 is not limited thereto and may be implemented in other ways. For example, the first impedance circuit 311_1 may include the second capacitor C2 and a second resistor R2 connected in parallel. For example, the first impedance circuit 311_1 may be implemented in various structures to operate as an HPF.

In some example embodiments, the first impedance circuit 311_1 may include a middle-frequency equalizer and a source-degeneration circuit. The middle-frequency equalizer and the source-degeneration circuit may be connected in parallel.

In some example embodiments, the first drive circuit 312 and the second drive circuit 313 may drive and/or output the first feedback signal F0 and the second feedback signal FB0 based on feedback signals F3 and FB3 received from another equalization block. For example, the first drive circuit 312 may include transistors M7, M8, and M9 that receive the seventh feedback signal F3 and transistors M10, M11, and M12 that receive respective tap coefficients W0B, W1B, and W2B corresponding to the seventh feedback signal F3. The transistors M7, M8, and M9 and the transistors M10, M11, and M12 may be PMOS transistors. The first drive circuit 312 may apply weighting to the first feedback signal F0 based on the seventh feedback signal F3 and the tap coefficients W0B, W1B, and W2B, which operate the transistors M7-M12. Likewise, for example, the second drive circuit 313 may include transistors M13, M14, and M15 that receive an eighth feedback signal FB3 and transistors M16, M17, and M18 that respectively receive tap coefficients W0B, W1B, and W2B corresponding to the eighth feedback signal FB3. The transistors M13, M14, and M15 and the transistors M16, M17, and M18 may be PMOS transistors. The second drive circuit 313 may apply weighting to the second feedback signal FB0 based on the eighth feedback signal FB3 and the tap coefficients W0B, W1B, and W2B, which operate the transistors M13-M18. Accordingly, a difference between the first feedback signal F0 and the second feedback signal FB0 may increase.

Consequently, frequency responses of the first feedback signal F0 and the second feedback signal FB0 may be determined based on voltage gain adjusted by the first impedance circuit 311_1 and weighting applied by the tap circuit.

A decision feedback equalizer according to some example embodiments of the present disclosure may compensate so that a high-frequency component of the signal is not weakened or distorted by amplifying voltage gain through placement of an impedance circuit in an input circuit that receives the data signal. Furthermore, because the impedance circuit is implemented to perform a middle-frequency equalization role that also amplifies voltage gain for a middle-frequency component, both a high-frequency band and a middle-frequency band may be improved, allowing for more effective suppression of inter-symbol influence.

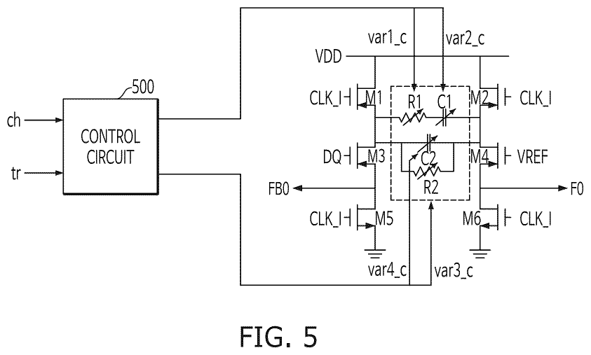

FIG. 5 illustrates some example embodiments of a control circuit that controls the input circuit of FIG. 4. Referring to FIGS. 4 and 5, a control circuit 500 may dynamically control frequency responses of the first feedback signal F0 and the second feedback signal FB0 by controlling impedances included in the first impedance circuit 311_1 of the first input circuit 311.

In some example embodiments, impedance elements included in the first impedance circuit 311_1 may be variable elements. For example, as described above, the first impedance circuit 311_1 may include the first capacitor C1 and the first resistor R1 connected in series and the second capacitor C2 and the second resistor R2 connected in parallel. The first capacitor C1, the second capacitor C2, the first resistor R1, and the second resistor R2 may be variable elements. The control circuit 500 may receive information about transmission characteristics ch of the channel and a transmission speed tr of the data signal DQ. For example, the transmission characteristics ch of the channel may include characteristics such as loss and/or attenuation (for example, insertion loss, return loss, skin effect, etc.) that weaken a signal frequency, phase delay/distortion characteristics, noise characteristics, environment (for example, temperature, dielectric) characteristics, and the like. The transmission characteristics ch of the channel may be information that encompasses one or more characteristics affecting signal distortion. The data-transmission speed tr may refer to a speed at which the data signal DQ is transmitted to the first input circuit 311 (for example, a speed at which the first device 10 of FIG. 1 transmits the data signal DQ to the second device 20 of FIG. 1). For example, when the host device transmits the data signal DQ to the memory device, the data-transmission speed tr may be information about whether the operating environment is high speed or low speed.

In some example embodiments, when an environment for transmitting the data signal DQ from the first device 10 to the second device 20 is a high-speed operating environment, probability of attenuation or distortion of a high-frequency component may be higher. Accordingly, the first device 10 may transmit information about the operating environment, for example, the data-transmission speed tr, in advance to the second device 20, and the control circuit 500 may adjust impedances of variable elements of the first impedance circuit 311_1 based on the received data-transmission speed tr. In some example embodiments, the control circuit 500 may adjust a resistance value of the first resistor R1 through a first control signal var1_c and may adjust a capacitance value of the first capacitor C1 through a second control signal var2_c. Likewise, the control circuit 500 may adjust a resistance value of the second resistor R2 through a third control signal var3_c and may adjust a capacitance value of the second capacitor C2 through a fourth control signal var4_c. For example, the control circuit 500 may adjust impedances of the variable elements so that high-frequency gain is amplified to more effectively compensate attenuation/distortion of a high-frequency component.

In some example embodiments, when an environment for transmitting the data signal DQ from the first device (for example, first device 10 of FIG. 1) to the second device 20 (for example, second device 20 of FIG. 1) is a low-speed operating environment, probability of attenuation or distortion of a high-frequency component may be relatively lower. Accordingly, the control circuit 500 may adjust impedances of variable elements of the first impedance circuit 311_1 based on the data-transmission speed tr indicating a low-speed operation. The control circuit 500 may also adjust impedances of the variable elements so that low-frequency gain is amplified to more effectively compensate attenuation/distortion of a low-frequency component.

In some example embodiments, to cope with various operating environments, the first impedance circuit 311_1 may be configured to activate/deactivate internal components. For example, the first impedance circuit 311_1 may additionally include separate switch transistors connected in series with the first resistor R1 and the first capacitor C1 and separate switch transistors connected in series with the second resistor R2 and the second capacitor C2. For example, in the operating environment having is lower speed or adjustment of frequency response based on the first impedance circuit 311_1 not performed, the control circuit 500 may deactivate the first impedance circuit 311_1 through control signals that deactivate the switch transistors. Alternatively, the control circuit 500 may disconnect the first impedance circuit 311_1 from the first receiving circuit 311a.

A decision feedback equalizer according to some example embodiments of the present disclosure may dynamically cope with various environments by variably controlling frequency responses of feedback signals through adjustment of impedance values of elements included in an input circuit based on characteristics of the channel and/or an operating environment (for example, transmission speed). Through this, the equalizer may be controlled to be optimized for both a high-speed operating environment and a low-speed operating environment.

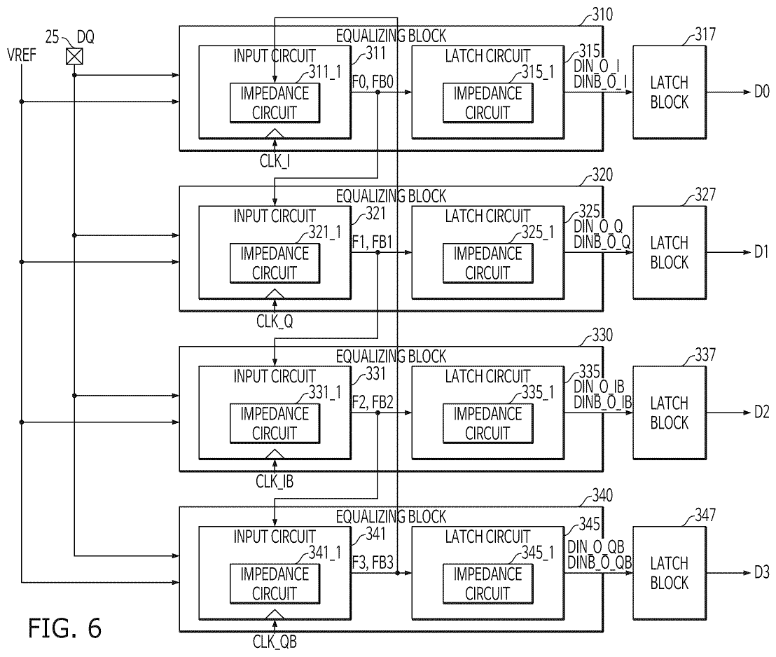

FIG. 6 is a block diagram illustrating a structure of a decision feedback equalizer according to some example embodiments of the present disclosure. Referring to FIG. 6, the receiving equalizer may include a plurality of equalization blocks 310, 320, 330, and 340. The plurality of equalization blocks 310, 320, 330, and 340 may operate based on clock signals having different phases and may provide feedback signals to other equalization blocks.

In some example embodiments, the receiving equalizer may receive a plurality of clock signals CLK_I, CLK_Q, CLK_IB, and CLK_QB. For example, a second clock signal CLK_Q may have a phase delayed by 90°relative to the first clock signal CLK_I. A third clock signal CLK_IB may have a phase delayed by 180°relative to the first clock signal CLK_I. A fourth clock signal CLK_QB may have a phase delayed by 270°relative to the first clock signal CLK_I. As described above, discussion for the first equalization block 310 with reference to FIGS. 1 through 5 may be applied in the same or a similar manner to the second equalization block 320, the third equalization block 330, and the fourth equalization block 340.

As described above, the first input circuit 311 of the first equalization block 310 may compare the reference voltage VREF and the data signal DQ, generate the first feedback signal F0 and the second feedback signal FB0, and adjust frequency responses of the first feedback signal F0 and the second feedback signal FB0 based on the first impedance circuit 311_1. The first feedback signal F0 and the second feedback signal FB0 may be provided to a second input circuit 321. The first latch circuit 315 may generate the first output signal DIN_O_I and the second output signal DINB_O_I based on a difference between the first feedback signal F0 and the second feedback signal FB0, and adjust frequency responses of the first output signal DIN_O_I and the second output signal DINB_O_I based on the second impedance circuit 315_1. Thereafter, the first latch block 317 may receive the first output signal DIN_O_I and the second output signal DINB_O_I and may output first data D0 (for example, restored data).

The second equalization block 320 may include the second input circuit 321 and a second latch circuit 325. The second input circuit 321 may compare the reference voltage VREF and the data signal DQ, generate a third feedback signal F1 and a fourth feedback signal FB1, and adjust frequency responses of the third feedback signal F1 and the fourth feedback signal FB1 based on a third impedance circuit 321_1. The third feedback signal F1 and the fourth feedback signal FB1 may be provided to a third input circuit 331. The second latch circuit 325 may generate a third output signal DIN_O_Q and a fourth output signal DINB_O_Q based on a difference between the third feedback signal F1 and the fourth feedback signal FB1, and adjust frequency responses of the third output signal DIN_O_Q and the fourth output signal DINB_O_Q based on a fourth impedance circuit 325_1. The second latch block 327 may receive the third output signal DIN_O_Q and the fourth output signal DINB_O_Q and output second data D1 (for example, restored data).

The third equalization block 330 may include the third input circuit 331 and a third latch circuit 335. Frequency responses of a fifth feedback signal F2 and a sixth feedback signal FB2 generated by the third input circuit 331 may be adjusted by a fifth impedance circuit 331_1, and the fifth feedback signal F2 and the sixth feedback signal FB2 may be provided to a fourth input circuit 341. Frequency responses of a fifth output signal DIN_O_IB and a sixth output signal DINB_O_IB generated by the third latch circuit 335 may be adjusted by a sixth impedance circuit 335_1. The third latch block 337 may receive the fifth output signal DIN_O_IB and the sixth output signal DINB_O_IB and may output third data D2 (for example, restored data).

The fourth equalization block 340 may include the fourth input circuit 341 and a fourth latch circuit 345. Frequency responses of a seventh feedback signal F3 and an eighth feedback signal FB3 generated by the fourth input circuit 341 may be adjusted by a seventh impedance circuit 341_1, and the seventh feedback signal F3 and the eighth feedback signal FB3 may be provided to the first input circuit 311 as described above. Frequency responses of a seventh output signal DIN_O_QB and an eighth output signal DINB_O_QB generated by the fourth latch circuit 345 may be adjusted by an eighth impedance circuit 345_1. The fourth latch block 347 may receive the seventh output signal DIN_O_QB and the eighth output signal DINB_O_QB and output fourth data D3 (for example, restored data). Through this structure, the receiving equalizer may divide and process the data signal DQ in four equalization blocks.

Through the above structure, a decision feedback equalizer according to some example embodiments of the present disclosure may process the data signal, which is received in a high-speed operating environment, in parallel to perform smoother equalization. For example, by dividing and processing data received at high speed, margins in power and process may be improved, an offset tolerance range may be improved, and a bit-error rate (BER) margin may increase.

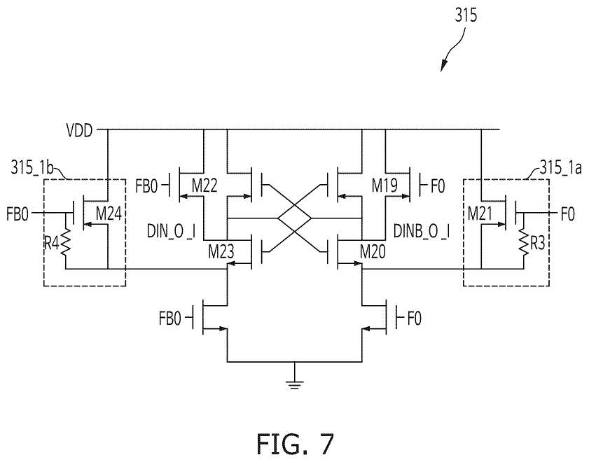

FIG. 7 is a circuit diagram illustrating a structure of a latch circuit according to some example embodiments of the present disclosure. The first latch circuit 315 may include a first sub-impedance circuit 315_1a and a second sub-impedance circuit 315_1b. The first sub-impedance circuit 315_1a and the second sub-impedance circuit 315_1b may be sub-circuits included in the second impedance circuit 315_1 of FIG. 3.

In some example embodiments, to compare the first feedback signal F0 and the second feedback signal FB0, the first latch circuit 315 may include a first output transistor M19, a third NMOS transistor M20, a second output transistor M22, and a fourth NMOS transistor M23. The first output transistor M19 and the second output transistor M22 may be PMOS transistors. A drain terminal of the first output transistor M19 may be connected to the power-supply voltage VDD, a source terminal of the first output transistor M19 may generate the second output signal DINB_O_I, and the first feedback signal F0 may be applied to a gate terminal of the first output transistor M19. A drain terminal of the third NMOS transistor M20 may be connected to the source of the first output transistor M19, a source terminal of the third NMOS transistor M20 may be connected to the first sub-impedance circuit 315_1a, and the first output signal DIN_O_I may be applied to a gate terminal of the third NMOS transistor M20. A drain terminal of the second output transistor M22 may be connected to the power-supply voltage VDD, a source terminal of the second output transistor M22 may generate the first output signal DIN_O_I, and the second feedback signal FB0 may be applied to a gate terminal of the second output transistor M22. A drain terminal of the fourth NMOS transistor M23 may be connected to the source of the second output transistor M22, a source terminal of the fourth NMOS transistor M23 may be connected to the second sub-impedance circuit 315_1b, and the second output signal DINB_O_I may be applied to a gate terminal of the fourth NMOS transistor M23. As illustrated, the third NMOS transistor M20 and the fourth NMOS transistor M23 may be connected to transistors M19 and M22 to form a cross-coupled structure.

In some example embodiments, the first sub-impedance circuit 315_1a may include a third resistor R3 and a first PMOS transistor M21. A drain terminal of the first PMOS transistor M21 may be connected to the power-supply voltage VDD, the first feedback signal F0 may be applied to a gate terminal of the first PMOS transistor M21, and source and gate terminals of the first PMOS transistor M21 may be respectively connected to the ends of the third resistor R3. The first sub-impedance circuit 315_1a may exhibit characteristics and effects of an inductance by using a resistance value of the third resistor R3 and parasitic capacitance of the first PMOS transistor M21. The first sub-impedance circuit 315_1a may be referred to as an active inductor, may operate like an inductor, and may adjust a frequency response of the first feedback signal F0. For example, the first sub-impedance circuit 315_1a may amplify (increase or peak) a high-frequency component of the first feedback signal F0. Likewise, the second sub-impedance circuit 315_1b may include a fourth resistor R4 and a second PMOS transistor M24. A drain terminal of the second PMOS transistor M24 may be connected to the power-supply voltage VDD, the second feedback signal FB0 may be applied to a gate terminal of the second PMOS transistor M24, and source and gate terminals of the second PMOS transistor M24 may be respectively connected to the ends of the fourth resistor R4. The second sub-impedance circuit 315_1b may also exhibit characteristics and effects of an inductance by using a resistance value of the fourth resistor R4 and parasitic capacitance of the second PMOS transistor M24. The second sub-impedance circuit 315_1b may be referred to as an active inductor, may operate like an inductor, and may adjust a frequency response of the second feedback signal FB0. For example, the second sub-impedance circuit 315_1b may amplify (or increase or peak) a high-frequency component of the second feedback signal FB0.

The first sub-impedance circuit 315_1a and the second sub-impedance circuit 315_1b are not limited to the example embodiments discussed herein and may be implemented in various other ways. For example, they may be implemented in circuits having an inductive effect or in circuits that amplify voltage gain of a high-frequency component.

A decision feedback equalizer according to some example embodiments of the present disclosure may compensate so that a high-frequency component of the signals is not weakened or distorted by amplifying voltage gain through placement of an impedance circuit in a latch circuit that receives feedback signals. In addition, by implementing respective sub-impedance circuits so that a signal adjusted in the latch circuit is re-amplified in a dual manner, a high-frequency band may be improved more effectively.

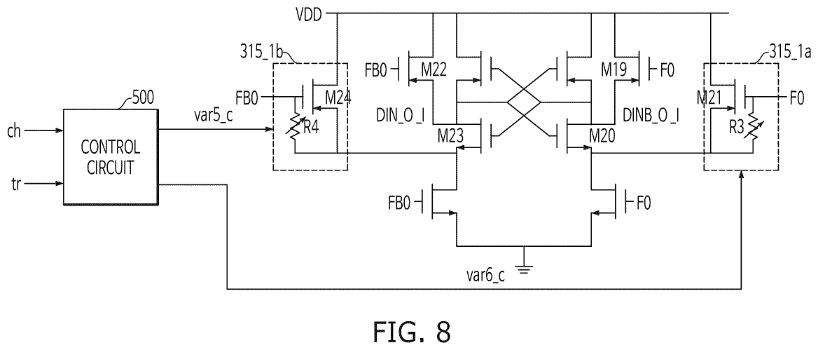

FIG. 8 illustrates some example embodiments of a control circuit that controls the latch circuit of FIG. 7. Referring to FIGS. 7 and 8, the control circuit 500 may dynamically control frequency responses of the first output signal DIN_O_I and the second output signal DINB_O_I by controlling impedances included in the first sub-impedance circuit 315_1a and the second sub-impedance circuit 315_1b of the first latch circuit 315.

In some example embodiments, resistors R3 and R4 included in the first sub-impedance circuit 315_1a and the second sub-impedance circuit 315_1b may be variable resistors. In some example embodiments, the control circuit 500 may receive information about the transmission characteristics ch of the channel and the transmission speed tr of the data signal DQ. As described above, the transmission characteristics ch of the channel may be or include information that encompasses all characteristics affecting signal distortion. The data-transmission speed tr may refer to a speed or frequency at which the data signal DQ is transmitted. For example, when the host device transmits the data signal DQ to the memory device, the data-transmission speed tr may be information about whether the operating environment is high speed or low speed.

In some example embodiments, when an operating environment is a relatively higher speed, probability of attenuation or distortion of a high-frequency component may be higher. Accordingly, the control circuit 500 may adjust resistance values of the variable resistors of the first sub-impedance circuit 315_1a and the second sub-impedance circuit 315_1b based on the data-transmission speed tr indicating the high-speed operating environment. In some example embodiments, the control circuit 500 may adjust a resistance value of the fourth resistor R4 through a fifth control signal var5_c and may adjust a resistance value of the third resistor R3 through a sixth control signal var6_c. In some example embodiments, the control circuit 500 may adjust resistance values of the variable resistors so that high-frequency gain is amplified to more effectively compensate attenuation/distortion of a high-frequency component.

In some example embodiments, when an operating environment is low speed, probability of attenuation or distortion of a high-frequency component may be relatively low. Accordingly, the control circuit 500 may adjust resistance values of the variable resistors of the first sub-impedance circuit 315_1a and the second sub-impedance circuit 315_1b based on the data-transmission speed tr indicating the low-speed operating environment. The control circuit 500 may also adjust impedances of variable elements so that low-frequency gain is amplified to more effectively compensate attenuation/distortion of a low-frequency component.

In some example embodiments, to cope with or adapt or adjust to different operating environments, the control circuit 500 may output a control signal that determines whether the first sub-impedance circuit 315_1a and the second sub-impedance circuit 315_1b are activated. For example, when the operating environment is low speed or adjustment of frequency response based on the second impedance circuit 315_1 is unnecessary, the control circuit 500 may deactivate the second impedance circuit 315_1 through a control signal that deactivates the first sub-impedance circuit 315_1a and the second sub-impedance circuit 315_1b. Alternatively, the control circuit 500 may disconnect the second impedance circuit (for example, second impedance circuit 315_1 of FIG. 6) from the first latch circuit 315 (for example, first latch circuit 315 of FIG. 6).

A decision feedback equalizer according to some example embodiments of the present disclosure may dynamically cope with or adapt or adjust to different environments by variably controlling frequency responses of output signals through adjustment of impedance values of variable elements included in a latch circuit based on characteristics of the channel and/or an operating environment (for example, transmission speed). As a result, the equalizer may be controlled to be optimized for both a high-speed operating environment and a low-speed operating environment.

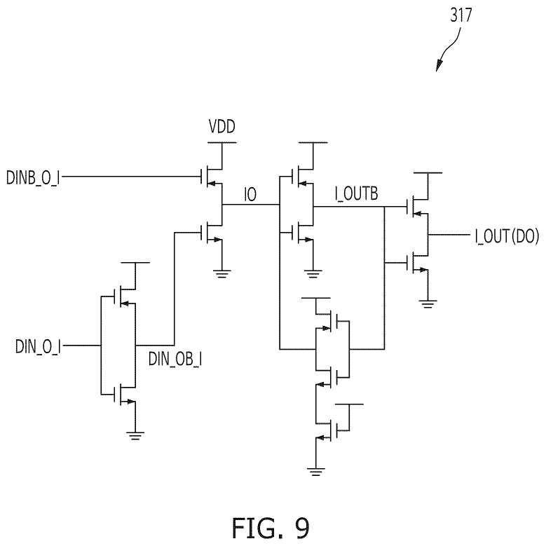

FIG. 9 is a circuit diagram illustrating a structure of a latch block according to some example embodiments of the present disclosure.

Referring to FIG. 9, the first latch block 317 may include transistors that receive the first output signal DIN_O_I and the second output signal DINB_O_I generated by the first latch circuit 315. The first latch block 317 may output first data D0 included in the data signal DQ based on the first output signal DIN_O_I and the second output signal DINB_O_I. An output signal I_OUT of the first latch block 317 may correspond to the first data D0.

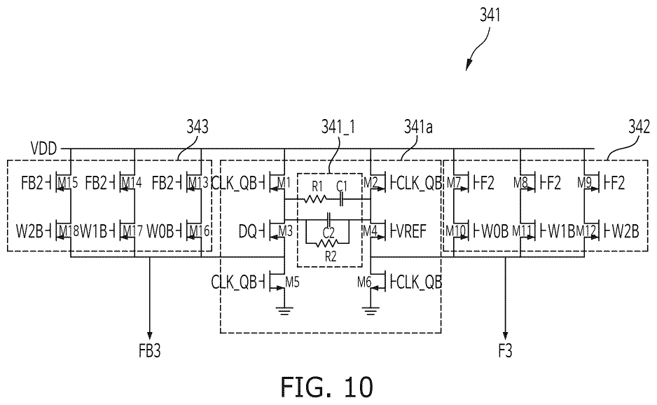

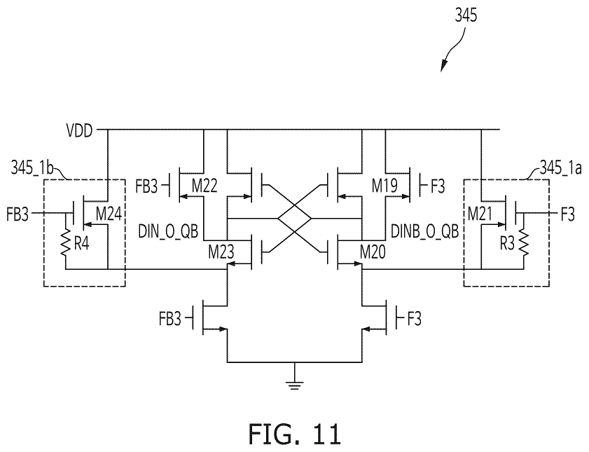

FIGS. 10 and 11 are circuit diagrams illustrating an input circuit and a latch circuit according to some example embodiments of the present disclosure. The example embodiments are described using a structure of the fourth equalization block 340 of FIG. 6 as an example, and the description for the first equalization block 310 provided with reference to FIGS. 1 through 9 may be applied in the same or a similar manner.

Referring to FIG. 10, the fourth input circuit 341 may include a fourth receiving circuit 341a, a seventh drive circuit 342, and an eighth drive circuit 343. Referring to FIG. 11, the fourth latch circuit 345 may include a seventh sub-impedance circuit 345_1a and an eighth sub-impedance circuit 345_1b.

In some example embodiments, the fourth receiving circuit 341a may include a plurality of transistors and a seventh impedance circuit 341_1 to receive and compare the reference voltage VREF and the data signal DQ and may operate according to a fourth clock signal CLK_QB. The fourth receiving circuit 341a may directly receive the data signal DQ through the data pad, compare the data signal DQ with the reference voltage VREF, and output the seventh feedback signal F3 and the eighth feedback signal FB3. The fourth input circuit 341 may adjust frequency responses of the seventh feedback signal F3 and the eighth feedback signal FB3 based on the seventh impedance circuit 341_1. In some example embodiments, the seventh impedance circuit 341_1 may provide voltage gain (for example, high-frequency gain) according to frequency for a difference between the reference voltage VREF and the data signal DQ.

In some example embodiments, the seventh impedance circuit 341_1 may include a capacitor C1 and a resistor R1 connected in series and may adjust voltage gain of a middle-frequency band based on the capacitor C1 and the resistor R1. The seventh impedance circuit 341_1 may further include a separate capacitor C2 and adjust voltage gain of a high-frequency component based on the capacitor C2.

In some example embodiments, the seventh drive circuit 342 and the eighth drive circuit 343 may receive the fifth feedback signal F2 and the sixth feedback signal FB2 from the third equalization block 330. The seventh drive circuit 342 and the eighth drive circuit 343 may receive the fifth feedback signal F2 and the sixth feedback signal FB2, respectively, and may drive and/or output the seventh feedback signal F3 and the eighth feedback signal FB3 based on a plurality of transistors that apply weighting to the fifth feedback signal F2 and the sixth feedback signal FB2, and adjust frequency responses.

Referring to FIG. 11, in some example embodiments, the seventh sub-impedance circuit 345_1a and the eighth sub-impedance circuit 345_1b may exhibit characteristics and effects of an inductance by using resistance values of resistors R3 and R4 and parasitic capacitances of PMOS transistors M21 and M24, operate like inductors, and adjust frequency responses of the seventh output signal DIN_O_QB and the eighth output signal DINB_O_QB. For example, the seventh sub-impedance circuit 345_1a and the eighth sub-impedance circuit 345_1b may amplify (or increase or peak) high-frequency components of the seventh feedback signal F3 and the eighth feedback signal FB3.

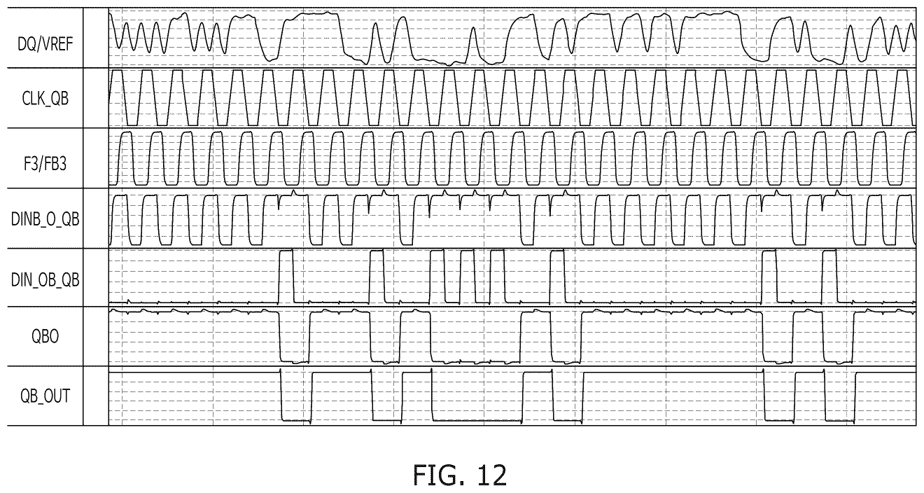

FIG. 12 is a timing diagram illustrating signals of the decision feedback equalizer of FIGS. 10 and 11. Example embodiments are described using signals of the fourth equalization block 340 of FIG. 6 and the fourth latch block 347 of FIG. 6 as examples. Referring to FIGS. 10, 11, and 12, the data signal DQ may be deteriorated due to noise such as inter-symbol interference when it is received through the channel and may have a waveform DQ/VREF as illustrated in FIG. 12.

The fourth equalization block 340 of FIG. 6 may operate according to the fourth clock signal CLK_QB and may generate the seventh feedback signal F3 and the eighth feedback signal FB3. For ease of illustration, FIG. 12 shows the seventh feedback signal F3 and the eighth feedback signal FB3 as a single signal. However, there is a difference between the seventh feedback signal F3 and the eighth feedback signal FB3. For example, a difference (for example, a phase difference or a magnitude difference at the same point in time) may exist in each cycle between the seventh feedback signal F3 and the eighth feedback signal FB3 according to a voltage difference between the reference voltage VREF and the data signal DQ. Frequency responses of the seventh feedback signal F3 and the eighth feedback signal FB3, for example, voltage gain according to frequency for the difference between the data signal DQ and the reference voltage VREF, may be adjusted by the seventh impedance circuit 341_1. For example, high-frequency gain of the difference between the seventh feedback signal F3 and the eighth feedback signal FB3 may increase.

Thereafter, the fourth equalization block 340 may latch a difference between the seventh feedback signal F3 and the eighth feedback signal FB3 and generate the seventh output signal DIN_O_QB and the eighth output signal DINB_O_QB. A difference (for example, a phase difference or a magnitude difference at the same point in time) may exist in each cycle between the seventh output signal DIN_O_QB and the eighth output signal DINB_O_QB according to the difference between the seventh feedback signal F3 and the eighth feedback signal FB3. Frequency responses of the seventh output signal DIN_O_QB and the eighth output signal DINB_O_QB, for example, voltage gain according to frequency for the difference between the seventh feedback signal F3 and the eighth feedback signal FB3, may be adjusted by the eighth impedance circuit 345_1 (including, the seventh sub-impedance circuit 345_1a and the eighth sub-impedance circuit 345_1b). For example, high-frequency gain of the difference between the seventh output signal DIN_O_QB and the eighth output signal DINB_O_QB may increase.

The fourth latch block (for example, fourth latch block 347 in FIG. 4) may invert the seventh output signal DIN_O_QB and generate an output signal QB_OUT based on an inverted seventh output signal DIN_OB_QB and the eighth output signal DINB_O_QB. In FIG. 12, QBO and QB_OUTB respectively illustrate signals of a QBO node (for example, a node of the fourth latch block 347 corresponding to an IO node of the first latch block 317 of FIG. 9) and a QB_OUTB node (for example, a node of the fourth latch block 347 corresponding to an I_OUTB node of the first latch block 317 of FIG. 9).

In FIG. 12, driving signals of the fourth equalization block 340 and the fourth latch block 347 are illustrated as examples. Driving signals of the other equalization blocks 310, 320, 330 and latch blocks 317, 327, 337 may be similar.

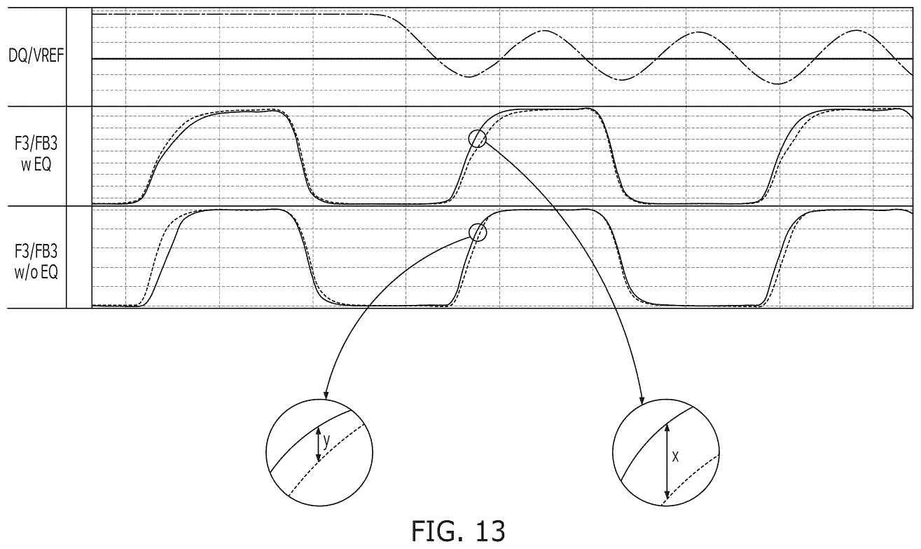

FIG. 13 is a diagram explaining effects of the decision feedback equalizer of FIGS. 10 and 11. In the figure, an F3/FB3 w EQ graph illustrates the seventh feedback signal F3 and the eighth feedback signal FB3 when the fourth equalization block 340 includes the seventh impedance circuit 341_1 and the eighth impedance circuit 345_1, and an F3/FB3 w/o EQ graph illustrates the seventh feedback signal F3 and the eighth feedback signal FB3 when the fourth equalization block 340 does not include the seventh impedance circuit 341_1 and the eighth impedance circuit 345_1.

A first interval x indicates a difference between the seventh feedback signal F3 and the eighth feedback signal FB3 at a specific or desired or given time when the fourth equalization block 340 includes the seventh impedance circuit 341_1 and the eighth impedance circuit 345_1. A second interval y indicates a difference between the seventh feedback signal F3 and the eighth feedback signal FB3 at the specific or desired or given time when the fourth equalization block 340 does not include the seventh impedance circuit 341_1 and the eighth impedance circuit 345_1.

The first interval x may be more than the second interval y. For example, the difference between the seventh feedback signal F3 and the eighth feedback signal FB3 may be relatively larger due to the seventh impedance circuit (for example, seventh impedance circuit 341_1 of FIG. 6). As the difference between the seventh feedback signal F3 and the eighth feedback signal FB3 becomes larger, the difference may be precisely latched in the fourth latch circuit (for example, fourth latch circuit 345 of FIG. 6). In addition, the difference between the seventh feedback signal F3 and the eighth feedback signal FB3 may become even larger due to the eighth impedance circuit of the fourth latch circuit (for example, eighth impedance circuit 345_1 of FIG. 6). Accordingly, a difference between the seventh output signal (for example, DIN_O_QB of FIG. 6) and the eighth output signal (for example DINB_O_QB of FIG. 6) may become more distinct or may increase (for example, an eye diagram may be more open).

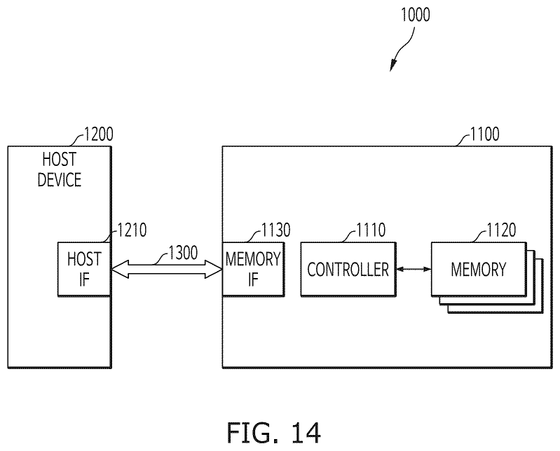

FIG. 14 is a block diagram illustrating a memory system according to some example embodiments of the present disclosure. Referring to FIG. 14, a memory device 1100 and a host device 1200 of a memory system 1000 may communicate through a channel 1300. The memory device 1100 may include a controller 1110, a memory 1120, and a memory interface 1130, and the host device 1200 may include a host interface 1210. The host interface 1210 and the memory interface 1130 may communicate through the channel 1300. The channel/interface 1300 may use electrical signals and/or optical signals and may be implemented, as a non-limiting example, as a serial advanced technology attachment (SATA) interface, a SATA Express interface, a serial attached SCSI (SAS) interface, a universal serial bus (USB) interface, or a combination thereof.

The host device 1200 may access the memory device 1100 through a request and may, for example, write or read data. The controller 1110 of the memory device 1100 may generally control the memory 1120 according to a request of the host device 1200. To perform data input/output operations on the memory device 1100, the host device 1200 may transmit a data signal and a data-strobe signal based on the host interface 1210, and the memory device 1100 may receive, using the memory interface 1130, the data signal (for example, the data signal DQ of FIG. 3) and the data-strobe signal (for example, the first clock signal CLK_I of FIG. 3) transmitted through the channel 1300. In some example embodiments, the memory interface 1130 may include the receiving equalizer 300 of FIG. 2. The memory interface 1130 may include the receiving equalizer 300 having a decision feedback equalizer structure, and may include at least one of the first input circuit 311 and the first latch circuit 315 of FIG. 3. Based on this, the memory interface 1130 may adjust frequency responses of internal signals (for example, feedback signals) used to restore data and may amplify voltage gain. Accordingly, even in a high-speed interface environment, the memory system 1000 may sufficiently or adequately secure bandwidth, may enlarge a timing margin, and may improve accuracy of data reception. In some example embodiments, the host interface 1210 of the host device 1200, which receives data transmitted from the memory device 1100, may also include the receiving equalizer 300 of FIG. 2.

The memory device 1100 may communicate with the host device 1200 by being removably coupled to the host device 1200. The memory 1120 may be nonvolatile memory, and the memory device 1100 may be referred to as a storage system. For example, the memory device 1100 may be implemented as a solid-state drive (SSD), an embedded SSD (eSSD), a multimedia card (MMC), or an embedded MMC (eMMC). However, the memory device 1100 is not limited thereto and may be variously implemented. For example, the memory device 1100 may be implemented as various volatile memories, and may be DRAM, double-data-rate 5(DDR5) synchronous DRAM, low-power DDR5 SDRAM, or DDR6 SDRAM.

According to some example embodiments, a method of operating a memory device comprises, receiving a data signal via a data pad, equalizing the data signal received through the data pad using a decision feedback equalizer by, generating, using a first input circuit of the decision feedback equalizer, a first feedback signal and a second feedback signal based on the data signal and a reference voltage according to a first clock signal; generating, using a first latch circuit of the decision feedback equalizer, a first output signal and a second output signal based on the first feedback signal and the second feedback signal; and at least one of adjusting frequency responses of the first feedback signal and the second feedback signal using a first impedance circuit included in the first input circuit; or adjusting frequency responses of the first output signal and the second output signal using a second impedance circuit included in the first latch circuit. According to some example embodiments, the method further comprises adjusting, using a first impedance circuit, a voltage gain according to frequency for a difference between the data signal and the reference voltage. According to some example embodiments, the first input circuit comprises, a first input transistor having a drain terminal connected to the first impedance circuit, a source terminal configured to output the second feedback signal, and a gate terminal configured to receive the data signal; a second input transistor having a drain terminal connected to the first impedance circuit, a source terminal configured to output the first feedback signal, and a gate terminal configured to receive the reference voltage; a first switch transistor having a drain terminal connected to a power-supply voltage, a source terminal connected to the first impedance circuit and the first input transistor, and a gate terminal configured to receive the first clock signal; and a second switch transistor having a drain terminal connected to the power-supply voltage, a source terminal connected to the first impedance circuit and the second input transistor, and a gate terminal configured to receive the first clock signal. According to some example embodiments, the first impedance circuit comprises a capacitor, or a capacitor and a resistor connected in parallel. According to some example embodiments, wherein the first impedance circuit comprises a capacitor and a resistor connected in series. According to some example embodiments, at least one of the capacitor or the resistor is a variable element, and the method comprises controlling and impedance of the variable element using a control circuit of the memory device. According to some example embodiments, the method further comprises outputting, using the control circuit, a control signal to adjust the impedance of the variable element based on at least one of channel transmission characteristics or a transmission speed of the data signal.

As described herein, any devices, systems, modules, portions, units, controllers, circuits, and/or portions thereof according to any of the example embodiments, and/or any portions thereof (including, without limitation, the controller 1110, the memory 1120, the memory interface 1130, the host device 1200, the host interface 1210, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device comprising:
a data pad configured to receive a data signal; and
a decision feedback equalizer configured to equalize the data signal received through the data pad,
wherein the decision feedback equalizer comprises,
a first input circuit configured to generate a first feedback signal and a second feedback signal based on the data signal and a reference voltage according to a first clock signal; and
a first latch circuit configured to generate a first output signal and a second output signal based on the first feedback signal and the second feedback signal,
wherein the memory device further comprises at least one of,
a first impedance circuit included in the first input circuit and configured to adjust frequency responses of the first feedback signal and the second feedback signal; or
a second impedance circuit included in the first latch circuit and configured to adjust frequency responses of the first output signal and the second output signal.

2. The memory device as claimed in claim 1,
wherein the first impedance circuit is further configured to adjust a voltage gain according to frequency for a difference between the data signal and the reference voltage.

3. The memory device as claimed in claim 1,
wherein the first input circuit comprises:
a first input transistor having a drain terminal connected to the first impedance circuit, a source terminal configured to output the second feedback signal, and a gate terminal configured to receive the data signal;
a second input transistor having a drain terminal connected to the first impedance circuit, a source terminal configured to output the first feedback signal, and a gate terminal configured to receive the reference voltage;
a first switch transistor having a drain terminal connected to a power-supply voltage, a source terminal connected to the first impedance circuit and the first input transistor, and a gate terminal configured to receive the first clock signal; and
a second switch transistor having a drain terminal connected to the power-supply voltage, a source terminal connected to the first impedance circuit and the second input transistor, and a gate terminal configured to receive the first clock signal.

4. The memory device as claimed in claim 3,
wherein the first impedance circuit comprises a capacitor, or a capacitor and a resistor connected in parallel.

5. The memory device as claimed in claim 3,
wherein the first impedance circuit comprises a capacitor and a resistor connected in series.

6. The memory device as claimed in claim 4,
wherein at least one of the capacitor or the resistor is a variable element, and
the memory device further comprises a control circuit configured to control impedance of the variable element.

7. The memory device as claimed in claim 6,
wherein the control circuit is further configured to output a control signal to adjust the impedance of the variable element based on at least one of channel transmission characteristics or a transmission speed of the data signal.

8. The memory device as claimed in claim 1,
wherein the data pad is configured to receive the data signal through a channel, and
the first input circuit is connected to the data pad and is configured to receive the data signal.

9. The memory device as claimed in claim 1,
wherein the decision feedback equalizer further comprises:
a second input circuit configured to generate a third feedback signal and a fourth feedback signal based on the data signal and the reference voltage according to a second clock signal having a different phase from the first clock signal; and
a second latch circuit configured to generate a third output signal and a fourth output signal based on the third feedback signal and the fourth feedback signal, and
wherein the memory device further comprises a tap circuit configured to output the first feedback signal and the second feedback signal based on the third feedback signal and the fourth feedback signal.

10. The memory device as claimed in claim 9,
wherein the tap circuit comprises:
a first drive circuit configured to output the first feedback signal based on the third feedback signal and a corresponding tap coefficient; and
a second drive circuit configured to output the second feedback signal based on the fourth feedback signal and the corresponding tap coefficient.

11. The memory device as claimed in claim 1,
wherein the second impedance circuit comprises:
a first sub-impedance circuit configured to adjust voltage gain of the first feedback signal according to frequency; and
a second sub-impedance circuit configured to adjust voltage gain of the second feedback signal according to frequency.

12. The memory device as claimed in claim 11,
wherein the first latch circuit comprises:
a first output transistor having a drain terminal connected to a power-supply voltage, a source terminal configured to output the second output signal, and a gate terminal configured to receive the first feedback signal;
a second output transistor having a drain terminal connected to the power-supply voltage, a source terminal configured to output the first output signal, and a gate terminal configured to receive the second feedback signal;
a first NMOS (n-channel metal-oxide-semiconductor) transistor having a drain terminal connected to the first output transistor, a source terminal connected to the first sub-impedance circuit, and a gate terminal configured to receive the first output signal; and
a second NMOS transistor having a drain terminal connected to the second output transistor, a source terminal connected to the second sub-impedance circuit, and a gate terminal configured to receive the second output signal.

13. The memory device as claimed in claim 12,
wherein the first sub-impedance circuit and the second sub-impedance circuit comprise a first active inductor and a second active inductor, respectively.

14. The memory device as claimed in claim 13,
wherein the first active inductor comprises,
a first resistor; and
a first PMOS (p-channel metal-oxide-semiconductor) transistor having a drain terminal connected to the power-supply voltage, a gate terminal configured to receive the first feedback signal, and a source terminal connected to a first end of the first resistor, wherein the gate terminal of the first PMOS is connected to a second end of the first resistor,
and the second active inductor comprises,
a second resistor; and
a second PMOS transistor having a drain terminal connected to the power-supply voltage, a gate terminal receiving the second feedback signal, and a source terminal connected to a first end of the second resistor, wherein the gate terminal of the second PMOS transistor is connected to a second end of the second resistor.

15. The memory device as claimed in claim 14,
wherein at least one of the first resistor or the second resistor is a variable resistor, and
the memory device further comprises a control circuit configured to control an impedance of the variable resistor.

16. The memory device as claimed in claim 15,
wherein the control circuit is further configured to output a control signal to adjust the impedance of the variable resistor based on at least one of channel transmission characteristics or a transmission speed of the data signal.

17. A memory device comprising:
a data pad configured to receive a data signal; and
a decision feedback equalizer comprising a plurality of equalization blocks configured to equalize the data signal received through the data pad,
wherein each of the plurality of equalization blocks comprises,
an input circuit configured to generate a first feedback signal and a second feedback signal based on the data signal and a reference voltage according to a clock signal; and
a latch circuit configured to generate a first output signal and a second output signal based on the first feedback signal and the second feedback signal,
wherein the input circuit comprises at least one of a source-degeneration circuit or a middle-frequency equalizer configured to adjust frequency responses of the first feedback signal and the second feedback signal, and
wherein the latch circuit comprises an active inductor circuit configured to adjust frequency responses of the first output signal and the second output signal.

18. The memory device as claimed in claim 17,
wherein the plurality of equalization blocks further comprises:
a first equalization block corresponding to a first clock signal;
a second equalization block corresponding to a second clock signal having a phase delayed by 90° compared to the first clock signal;
a third equalization block corresponding to a third clock signal having a phase delayed by 180° compared to the first clock signal; and
a fourth equalization block corresponding to a fourth clock signal having a phase delayed by 270° compared to the first clock signal, wherein
the input circuit of the second equalization block is configured to receive feedback signals generated by the input circuit of the first equalization block,
the input circuit of the third equalization block is configured to receive feedback signals generated by the input circuit of the second equalization block,
the input circuit of the fourth equalization block is configured to receive feedback signals generated by the input circuit of the third equalization block, and
the input circuit of the first equalization block is configured to receive feedback signals generated by the input circuit of the fourth equalization block.

19. The memory device as claimed in claim 17,
wherein the input circuit comprises,
a first input transistor having a drain terminal connected to the at least one of the source-degeneration circuit and the middle-frequency equalizer, a source terminal configured to output the second feedback signal, and a gate terminal configured to receive the data signal;
a second input transistor having a drain terminal connected to the at least one of the source-degeneration circuit and the middle-frequency equalizer, a source terminal configured to output the first feedback signal, and a gate terminal configured to receive the reference voltage;
a first switch transistor having a drain terminal connected to a power-supply voltage, a source terminal connected to at the least one of the source-degeneration circuit or the middle-frequency equalizer, and the first input transistor, and a gate terminal configured to receive the clock signal; and
a second switch transistor having a drain terminal connected to the power-supply voltage, a source terminal connected to the at least one of the source-degeneration circuit or the middle-frequency equalizer, and the second input transistor, and a gate terminal configured to receive the clock signal,
wherein the latch circuit comprises,
a first output transistor having a drain terminal connected to the power-supply voltage, a source terminal configured to output the second output signal, and a gate terminal configured to receive the first feedback signal;
a second output transistor having a drain terminal connected to the power-supply voltage, a source terminal configured to output the first output signal, and a gate terminal configured to receive the second feedback signal;
a first NMOS transistor having a drain terminal connected to the first output transistor, a source terminal connected to the active inductor circuit, and a gate terminal configured to receive the first output signal; and
a second NMOS transistor having a drain terminal connected to the second output transistor, a source terminal connected to the active inductor circuit, and a gate terminal configured to receive the second output signal.

20. A memory system comprising:
a host device; and
a memory device configured to receive a data signal from the host device through a memory interface comprising a decision feedback equalizer,
wherein the decision feedback equalizer comprises,
an input circuit configured to generate a first feedback signal and a second feedback signal based on the data signal and a reference voltage according to a clock signal; and
a latch circuit configured to generate a first output signal and a second output signal based on the first feedback signal and the second feedback signal, wherein
the input circuit comprises a first impedance circuit configured to provide voltage gain to a difference between the data signal and the reference voltage, and
the latch circuit comprises a second impedance circuit configured to provide voltage gain to a difference between the first feedback signal and the second feedback signal generated based on the first impedance circuit.
